(19) United States
(12) Patent Application Publication
(10) Pub. No.: US 2014/0238850 A1
(43) Pub. Date: Aug. 28, 2014

(54) TUBULAR TARGET AND METHOD OF PRODUCING A TUBULAR TARGET

(71) Applicant: PLANSEE SE, REUTTE (AT)

(72) Inventors: Peter Abenthung, Reutte (AT); Christian Linke, Ehenbichl (AT); Andre Dronhofer, Reutte (AT); Hartmut Wolf, Breitenwang (AT); Tobias Will, Weinstadt-Beutelsbach (DE); Wolfgang Koeck, Reutte (AT)

(73) Assignee: Plansee SE, REUTTE (AT)

(21) Appl. No.: 14/352,725

(22) PCT Filed: Oct. 17, 2012
(86) PCT No.: PCT/AT2012/000262

§ 371 Date: Apr. 18, 2014

(30) Foreign Application Priority Data
Oct. 18, 2011 (AT) GM 562/2011

(51) Int. Cl. C23C 14/34

(52) U.S. Cl. CPC C23C 14/3414; C23C 14/3407
USPC 204/298.13; 419/5

(57) ABSTRACT

A tubular target is formed of refractory metal or a refractory metal alloy. The target has at least one tubular portion X with a relative density RDx and at least one tubular portion Y with a relative density RDy. At least one tubular portion X has, at least in some regions, a larger outer diameter than a tubular portion Y at least in some regions. A density ratio satisfies the relation (RDy−RDx)/RDy≧0.001. There is also described a method for producing a tubular target from refractory metal or refractory metal alloy by sintering and local deformation of different degree. The tubular target has a more uniform sputter removal over the entire surface area compared with prior tubular targets. The tubular targets do not exhibit any tendency to arcing or to particle regeneration.

The invention relates to a tubular target composed of refractory metal or a refractory metal alloy having a refractory metal content of >50 atom %, which comprises at least one tubular section X having a relative density RDx and at least one tubular section Y having a relative density RDy, where at least one tubular section X has at least in regions a greater external diameter than at least in regions a tubular section Y.

The invention further relates to a process for producing a tubular target composed of a refractory metal or a refractory metal alloy having a refractory metal content of >50 atom %, where the process comprises at least the following steps: production of a green body by pressing a powder at a pressing pressure p, where 100 MPa <p<400 MPa, and production of a tubular blank by pressureless or pressure-aided sintering at a homologous temperature of from 0.4 to 0.9 and optionally mechanical shaping.

A tubular target is a tubular atomization source for a cathode atomization unit. Cathode atomization is usually also referred to as sputtering and the atomization sources are referred to as sputtering targets. A tubular target is therefore a sputtering target having a tubular shape. A process frequently used particularly in microelectronics is magnetron sputtering. While only an electric field is applied during simple cathode atomization, a magnetic field is additionally generated in the case of magnetron sputtering. The superposition of an electric field and a magnetic field lengthens the path of the charge carriers and increases the number of impacts per electron.

An advantage of tubular targets is the uniform ablation and thus a high degree of utilization. For the purposes of the present invention, the degree of utilization is the mass of material which has been sputtered off during the entire time for which the target is used, based on the mass of the target before the first use. Thus, the degree of utilization for planar targets is from about 15 to 40% and that for tubular targets is typically from 75 to 85%. The target cooling achieved in the interior space of the tubular target is significantly more effective than in the case of planar targets as a result of the better heat transfer in the tube, which makes higher surface energy densities and thus higher coating rates possible. In addition, the tendency for local electric arc formation (also referred to as arcing) to occur is also reduced, especially in the case of reactive sputtering. The use of tubular targets is particularly advantageous when large-area substrates are coated. During use, the tubular target rotates slowly while the magnetic field is usually stationary. The electron density is highest at the point where the Lorentz force is parallel to the target surface. This brings about greater ionization in this region. Although the sputtering ablation can be equalized to a certain extent over the length of the target by means of an optimized arrangement of the magnets, this is higher in the region of the ends of the tube than in the middle region of the tubular target. As a result of the increased ablation in the region of the ends of the tube, the regions of the substrate to be coated which are located directly in the vicinity of the ends of the tubular target are coated with a different layer thickness than the rest of the substrate. The increased ablation at the ends of the tube also limits the possible materials utilization of the tubular target since a certain residual amount of target material remains, in particular, in the middle region of the tubular target after the end of the coating process and can thus not be utilized for coating. This limits the degree of utilization.

U.S. Pat. No. 5,853,816 (A) describes a tubular target in which the ends have a greater external diameter than the middle region of the tubular target. The materials utilization of the target can be significantly increased in this way. This process is suitable for target materials which are applied by thermal spraying. In other production processes, however, this geometry can only be obtained by means of additional processing steps and increased usage of material. In addition, the possible increase in the thickness of the material at the ends of the target is determined by the weakening of the magnetic field strength, which has to be taken into account particularly in the case of refractory metals when the amount of material deposited is too high. In addition, although the usage time of the tubular targets is increased when tubular targets which have a greater external diameter in the region of the ends of the tube are used, the nonuniform ablation cannot be avoided.

WO 2007/141173 A1 and WO 2007/141174 A1 have the objective of equalizing this nonuniform ablation.

In WO 2007/141174 A1, this is achieved by end regions of the tube which are formed by a material which contains a chemical compound of one of the elements present in the middle region. In WO 2007/141173 A1, this end region is produced by thermal spraying. However, for applications in, more particularly, the field of microelectronics, there is a desire to use sputtering targets having a homogeneous materials composition because of the very high demands made of the materials homogeneity of the deposited layer.

The production of tubular targets having a relatively high degree of utilization as a result of the attachment of end pieces made of a different material than the target material to be sputtered is described in U.S. Pat. No. 5,725,746 (A). This additional material is sputtered at a slower ablation rate than the actual target material. However, impurities are introduced into the thin layer. In addition, tubular targets without a support tube cannot be produced by this process.

Tubular targets are used predominantly for producing large-area coatings. The high degree of utilization of the target material is an advantage, especially in the case of expensive layer materials such as refractory metals. For the purposes of the present invention, a refractory metal is a metal of transition group 4 (titanium, zirconium and hafnium), transition group 5 (vanadium, niobium and tantalum), of transition group 6 (chromium, molybdenum and tungsten) and also rhenium. The melting point of such metals is above that of platinum (1772° C.). Refractory metals have a property profile which is of great interest for many applications. Owing to the high melting point, the foreign diffusion rate is in principle low, which predestines them for use as diffusion barriers. Furthermore, molybdenum and tungsten in particular form an ohmic contact with many layer materials, as a result of which a Schottky barrier is avoided. The high electrical conductivity, especially of molybdenum, tungsten and chromium, is advantageous for use as conductor track. The low coefficient of thermal expansion, especially of molybdenum, tungsten and chromium, ensures good adhesion of the layer and low layer stresses when deposited on glass substrates. Sputtering targets composed of refractory metals are still preferably planar.

Many production processes for producing tubular targets composed of refractory metals, for example casting processes; hot isostatic pressing, sintering, extrusion or various spraying techniques have already been tried. An advantageous powder-metallurgical production process for tubular molybdenum targets is described, for example, in WO 2007/041730 A1.

It is therefore an object of the invention to provide a tubular target which does not have at least one of the disadvantages indicated in the prior art. A further object of the invention is to provide a tubular target which is ablated uniformly in the sputtering process and does not tend to display a locally unacceptably increased sputtering rate. Furthermore, it is an object of the invention to provide a tubular target which has a high degree of utilization.

A further object of the invention is to provide a tubular target by means of which layers having a high uniformity of the layer thickness can be deposited over a large area. In addition, it is an object of the invention to provide a tubular target which has a very low tendency to display local electric arc formation (arcing) and particle generation. A further object of the invention is to provide an inexpensive process for producing tubular targets, which has at least one of the abovementioned properties.

The object is achieved by the independent claims.

The tubular target comprises at least one tubular section X having at least in regions a relative density RDx and at least one tubular section Y having at least in regions a relative density RDy. The tubular section X has at least in regions a greater external diameter than at least in regions the tubular section Y. The density ratio satisfies the following relationship at least in region: (RDy−RDx)/RDy≧0.001. If the density ratio is lower, the advantages indicated below are no longer achieved to a sufficient extent. For the present purposes, the relative density is the measured density based on the theoretical density of the respective material. The theoretical density of a material corresponds to the density of pore-free, 100% dense material. The advantageous effect of the invention is ensured in the case of refractory metals and refractory metal alloys. Refractory metals and refractory metal alloys have a high sputtering stability. Refractory metals encompass the metals of transition group 4 (titanium, zirconium and hafnium), of transition group 5 (vanadium, niobium and tantalum), of transition group 6 (chromium, molybdenum and tungsten) and also rhenium. For the purposes of the present invention, a refractory metal alloy is an alloy of at least one or more than one refractory metals, where the total refractory metal content is greater than/equal to 50 atom %. In the case of refractory metals and refractory metal alloys, a very small density difference between the tubular sections X and Y is sufficient to achieve more uniform sputtering ablation. Particularly preferred refractory metals are the comparatively brittle materials of transition group 6, namely chromium, molybdenum, tungsten, and their alloys. Furthermore, molybdenum and molybdenum alloys are to be emphasized.

The density is determined according to the Archimedes principle which describes the relationship between mass, volume and density of a solid body immersed in liquid. The weight minus the buoyancy force is determined by the buoyancy method and the relative density is calculated from this and the weight of air.

The sampling to determine RDx and RDy is described below. The buoyancy method enables the density of small volumes to be determined reliably. In the determination of the density of a tubular section of a tubular target, the minimal volume is determined by the minimum thickness of a slice of the tubular section. The minimum achievable thickness is in turn determined by the expertise of machining. A slice of the tubular section having a thickness of 3 mm can be reliably produced regardless of the available expertise and is therefore used as a basis for the determination of RDx and RDy. The specimens are preferably taken in the region of the greatest external diameter of the tubular section X and in the region of the smallest external diameter of the tubular section Y.

It has now been found that the sputtering ablation is more uniform over the length of the tubular target in the case of a tubular target having the inventive features than in the case of targets according to the prior art. A more uniform sputtering ablation over the length of the tubular target ensures a high degree of utilization. The degree of utilization depends on the RDy:RDx ratio, on the sputtering parameters, for example the bias voltage, and on the material being sputtered. Furthermore, uniform sputtering ablation also means a uniform sputtering rate. A uniform sputtering rate over the length of the tubular target in turn leads to deposited layers which have a very uniform layer thickness over the entire area. This uniform layer thickness is achieved even in the case of layers deposited over a large area. Furthermore, it has been found that the tubular targets of the invention have a tendency neither to unacceptably strong arcing nor to particle generation and thus bring about fewer defects in the layer.

The average relative densities RDxm and RDym of a relatively large volume are preferably determined, where RDxm denotes the average relative density of at least a region of the tubular section X and RDym denotes the average relative density of at least a region of the tubular section Y. To determine RDxm and RDym, a tubular section having a thickness of 50 mm is taken. The specimens for the density determination are preferably taken in the region of the greatest external diameter of the tubular section X and of the smallest external diameter of the tubular section Y. The values of RDx and RDxm are preferably identical. The values of RDy and RDym, too, are preferably identical. Furthermore, the ratio of the average relative densities (RDym−RDxm)/RDym is preferably ≧0.001.

In another preferred embodiment, at least one ratio of the relative densities of the group (RDy−RDx)/RDy and (RDym−RDxm)/RDym is ≧0.005 or ≧0.01 or ≧0.02 or ≧0.05 or ≧0.1. The optimum ratio depends on the sputtering conditions and the material being sputtered. A very uniform sputtering behaviour is obtained in this way. Furthermore, at least one ratio from the group (RDy−RDx)/RDy and (RDym−RDxm)/RDym is preferably 0.2. If the ratio of the relative densities or of the average relative densities is greater than 0.2, the region X has a comparatively low density, as a result of which, depending on the material and the sputtering parameters, increased particle generation and/or local arcing can occur.

Furthermore, it is advantageous for the relative density of the tubular section Y to be from 99 to 100%. The tubular section X preferably has a fine and uniform pore structure. This ensures a very low tendency for particle generation and arcing to occur. A fine and uniform pore structure is preferably achieved when the tubular target has been produced by powder metallurgy. Powder-metallurgical production results in micro structural features, for example size and distribution of the residual porosity, which cannot be produced by melt metallurgy. Thus, the average pore diameter in the tubular section X is preferably from 10 nm to 10 μm.

Furthermore, preference is given to at least regions of the ends of the tubular target to be configured as tubular section X. Preference is given to at least one tubular section Y being located between the tubular sections X. The tubular section Y preferably extends in the axial direction over a greater region than the sum of the two tubular sections X. This ensures that the tubular sections X are arranged where the greatest plasma density occurs.

Furthermore, preference is given to all tubular sections X and all tubular sections Y having the same materials composition. The composition of the tubular sections X and Y is preferably within the range specified for the respective material. In other words, the entire tubular target is made of the same material. This is very advantageous, especially for applications in the field of electronics, since even slight concentration differences have a great influence in the functional properties of the layer.

Furthermore, it is advantageous for the tubular target to be made in one piece. Joints as occur in the case of tubular targets made up of a number of joint pieces are avoided in this way. Tubular targets made in one piece have a lesser tendency for particle generation to occur.

Furthermore, the diameter ratio (ADx−ADy)/ADx at least in regions for a tubular section X and at least in regions for a tubular section Y is preferably ≧0.01, where ADx is the maximum external diameter of the tubular section X and ADy is the smallest external diameter of the tubular section Y. If the diameter ratio is below 0.01, the different ablation can be equalized only by means of a lower density in the tube section X. The ratio of the external diameters (ADx−ADy)/ADx is preferably ≧0.3. A greater ratio also means a locally different distance between tubular target and substrate.

In a preferred embodiment, the tubular target comprises two tubular sections X and one tubular section Y, with the tubular section Y being arranged between the tubular sections X. The transition between the tubular sections X and the tubular section Y can be gradual or sharp. A gradual transition means that a further section Z is arranged between tubular section X and tubular section Y, with the external diameter in the section Z changing from the external diameter of the adjoining region of tubular section X to the external diameter of the adjoining region of tubular section Y. In a further preferred embodiment, the tubular target has two tubular sections X having the same external diameter. In a further preferred embodiment, the tubular section Y has a constant external diameter over at least 80% of the length. In addition, the internal diameter is preferably constant over the entire length of the tubular target. In a further preferred embodiment, the external diameter changes from ADx to ADy in at least one tubular section X. In other words, the tubular section X is conical.

Furthermore, the tubular target can be monolithic or be joined to a support tube composed of a nonmagnetic material. Monolithic means that the connecting piece also consists of the material to be sputtered. If the tubular target is made up of more than one piece, the tubular sections X, Y and/or Z can be fixed in place by means of a support tube. The individual tube sections can be arranged merely next to one another or be joined to one another by means of a joining method such as diffusion welding. When the tubular target is joined to a support tube, this can be affected, for example, by means of a soldered join or a screw connection.

The tubular target is preferably used for coating tasks where the highest layer quality is required. In particular, this is the case in the production of rear contact layers of a thin-film solar cell, preferably made of molybdenum or a sodium-containing molybdenum material, or a functional layer of a TFT structure, preferably made of tungsten, molybdenum or a molybdenum alloy, for example Mo—Ta, Mo—W, Mo—Cr, Mo—Nb or Mo—Ti.

Furthermore, the objects of the invention are achieved by means of a process for producing a tubular target, where the tubular target consists of a refractory metal or a refractory metal alloy.

The production of the blank can be carried out largely by the process disclosed in EP 1 937 866 A1, namely by production of a green body by pressing a powder at a pressing pressure p, where 100 MPa<p<400 MPa; and production of a tubular blank by pressure less or pressure-aided sintering at a homologous temperature of from 0.4 to 0.9 and optionally mechanical shaping. A homologous temperature is a temperature ratio based on the absolute melting point of a material.

The tubular blank is then deformed in the region which in the finished tubular target corresponds to the tubular section Y so that the degree of deformation is at least in regions higher than in the region which in the finished tubular target corresponds to the tubular section X. The degree of deformation is a shape change parameter which describes the permanently geometric change in a workpiece in the forming process.

For deformation of a tube, the degree of deformation is defined as follows:

$$ϕ = ln \frac{A 1}{Ao} ,$$

where
A₁ . . . cross-sectional area in the respective final state,
A₀ . . . cross-sectional area in the respective initial state.

The tubular blank is preferably deformed in a region which corresponds in the finished tubular target to the tubular section Y at least in regions by |φ|≧0.03 to a greater extent than at least in regions in a region which in the finished tubular target corresponds to the tubular section X. Since a reduction in the cross section leads to a negative value for φ, the absolute value |φ| is reported. The absolute value |φ| is obtained by leaving off the sign. |φ| is preferably ≧0.1, particularly preferably ≧0.3.

Furthermore, |φ| is preferably ≦3. If |φ| is <0.03 or |φ| is >3, the preferred density ratios can only be achieved with a greater processing engineering outlay.

It has now been found that the production process of the invention is particularly suitable for producing refractory metal alloys, while it is not advantageous for other materials, e.g. low-melting, very soft materials such as copper or aluminium.

In principle, a person skilled in the art will make a distinction between two forming techniques, namely melt-metallurgical and powder-metallurgical techniques. Melt-metallurgical techniques are disadvantageous since it is not possible to produce any porosity which consists of many small, very uniformly distributed pores. A further advantage of powder-metallurgical process techniques is that a sintered body having a defined relative density can be produced from a porous green body. The densification process can also be carried out so that a microstructure which is particularly advantageous for uniform sputtering ablation is formed.

It is in principle also possible to produce regions having differing densities in the green body itself. Thus, the green body can, for example, be produced in such a way that it has, even in the green state, regions having a relatively low density and regions having a relatively high density corresponding to the density values to be achieved in the tubular target. The production of the green body is preferably carried out by cold isostatic pressing. Here, the powder is typically introduced into a flexible tube which is sealed on all sides and positioned in a cold isostatic press. In the cold isostatic press, a liquid pressure which is preferably in the range from 100 to 400 MPa is applied, resulting in densification. If a powder having the same particle size is used over the entire length of the green body, the relative density and thus the porosity are also approximately constant over the entire length. However, if the tube is filled firstly with a fine powder, for example in the case of molybdenum or tungsten having an FSSS (FSSS=Fisher Subsieve Size) of from 1.5 to 3 μm in the region which later corresponds in the finished tubular target to the tubular section X and then with a powder having a larger particle size, in the case of molybdenum or tungsten, for example, having a FSSS of from 3 to 6 μm, in the region which corresponds to the tubular section Y in the finished tubular target, a different density distribution is achieved in the green status. The density is lower where the particle size is smaller and higher in the region having coarser powder particles. When, for example, further densification is effected by hot isostatic pressing at comparatively low temperatures, for example at a homologous temperature in the range from 0.4 to 0.6, a density difference remains even after the densification process. However, it is also possible to exploit the different sintering behaviour of fine and coarse powders; at the customary sintering temperature (homologous temperature of from 0.6 to 0.9) without application of pressure, a fine powder sinters significantly more strongly and thus densifies better than a green body made of coarser powder. This effect can be exploited as follows. A green body which has relatively coarse powder (in the case of molybdenum or tungsten, for example, having a FSSS of from 3 to 6 μm) in the region which later corresponds to the tubular section X and has fine powder (in the case of molybdenum or tungsten, for example, having a FSSS of from 1.5 to 3 μm) in the region which later corresponds to the tubular section Y is firstly produced. The green density is then higher in the tubular section X than in the tubular section Y. In a subsequent sintering process without application of pressure, typically in the homologous temperature range from 0.6 to 0.9, the region of the green body produced from the fine powder densifies to a greater extent than the region produced from coarser powder, as a result of which the different green densities are more than compensated.

Furthermore, the shape of the green body can be selected from the group consisting of a tube, a cylinder, a tube having a greater external diameter in regions and a cylinder having a greater external diameter in regions. If a cylinder is produced, a tubular body has to be produced by mechanical shaping after the sintering process. It is advantageous to press a tube right at the beginning. For this purpose, a mandrel is introduced into the rubber tube, as a result of which the hollow space of the tube is produced during pressing.

Furthermore, it can also be advantageous to produce a green body having a greater external diameter in the region of at least one end of the tube. However, it has been found to be very advantageous to produce a green body which has a uniform green density over its entire volume and also an approximately constant external diameter and internal diameter. Sintering is carried out in such a way that the average relative sintered density RDr satisfies the following relationship: 0.80≦RDr≦0.995. At a high RDr value, it can be advantageous, depending on the sputtering conditions, for the tubular section X not to be deformed. If the sintered density is less than 0.80, the sintered body can be deformed without defects only with some difficulty. In addition, the undesirable arcing and particle generation increase greatly. A sintered density above 0.995 leads to coarse grain formation. If a green body having a tubular shape is produced by pressing, the sintered body has a tubular shape and is referred to as tubular blank. The production of a tubular blank can also optionally be carried out mechanically. This mechanical shaping is indispensible when the green body is produced as a cylinder. The tubular blank can subsequently be subjected to predeformation over its entire length. Suitable forming processes are, for example, extrusion and forging. The predeformed tubular blank produced in this way preferably has a relative density of from 0.85 to 0.995.

The production of the more greatly deformed tubular section Y is preferably carried out by a process from the group consisting of forging and pressure rolling. The tubular blank is preferably deformed so that |φ|≧0.03 is greater at least in a region which in the finished tubular target corresponds at least partly to the tubular section Y than at least in a region which in the finished tubular target corresponds at least partly to the tubular section X. The tubular blank can also, as mentioned above, firstly be deformed by extrusion and/or forging. The predeformed tubular blank produced in this way is deformed by forging and/or pressure rolling so that |φ|≧0.03 is greater at least in a region which in the finished tubular target corresponds at least partly to the tubular section Y than at least in a region which in the finished tubular target corresponds at least partly to the tubular section X.

As forming temperature, the temperature customary for the respective material can be selected. The degree of deformation φ in the tubular section X is preferably such that −3≦φ≦0, particularly preferably −2.5≦φ≦0.3.

If a green body having a homogeneous density distribution is used, the local density can be reliably set by selection of the local degree of deformation. Influencing parameters are the shape of the green body and of the forged tube. The tubular blank preferably has a tubular shape with an approximately constant external diameter and internal diameter. The region corresponding to the tubular section X, preferably the ends of the tube is deformed to a lesser extent and the region corresponding to the tubular section Y is deformed to a greater extent. Since the density increases with increasing degree of deformation, the region Y has a higher density after forming. These methods allow production of a tubular target which has a very uniform sputtering behaviour and a low tendency for arcing and particle generation.

Preference is given to a tubular target which has been produced by the process of the invention and is characterized by one or more properties of the following group, namely that (RDy−RDx)/RDy≧0.001; it consists of a material from the group consisting of molybdenum, a molybdenum alloy, tungsten, a tungsten alloy, chromium and a chromium alloy; the ends of the tube are configured as tubular sections X and at least one region Y which extends over a greater region than the sum of the two tubular sections X is located between them; all tubular sections X and all tubular sections Y have an identical materials composition; it is made in one piece; at least one tubular section X has an average relative density RDxm over a length in the axial direction of 50 mm and at least one tubular section Y has an average relative density RDym over a length in the axial direction of 50 mm, where (RDym−RDxm)/RDym≧0.001; a ratio from the group (RDy−RDx)/RDy and (RDym-RDxm)/RDym is ≧0.01; at least one ratio from the group (RDy−RDx)/RDy and (RDym−RDxm)/RDym is ≦0.2; it has been produced by powder metallurgy; at least one tubular section X has a fine and uniform pore structure; the tubular section X has at least in regions a greater external diameter than the tubular section Y; at least one tubular section X has an external diameter ADx and at least one tubular section Y has an external diameter ADy, where (ADx−ADy)/ADx≧0.01; (ADx−ADy)/ADx≦0.3; a section Z is located between the tubular section X and the tubular section Y, with the external diameter in the section Z changing from ADx to ADy; at least one tube section X is conical; it is joined to a support tube composed of a nonmagnetic material; it is monolithic; and/or it is used for producing a rear contact layer of a thin-film solar cell or a functional layer of a TFT structure.

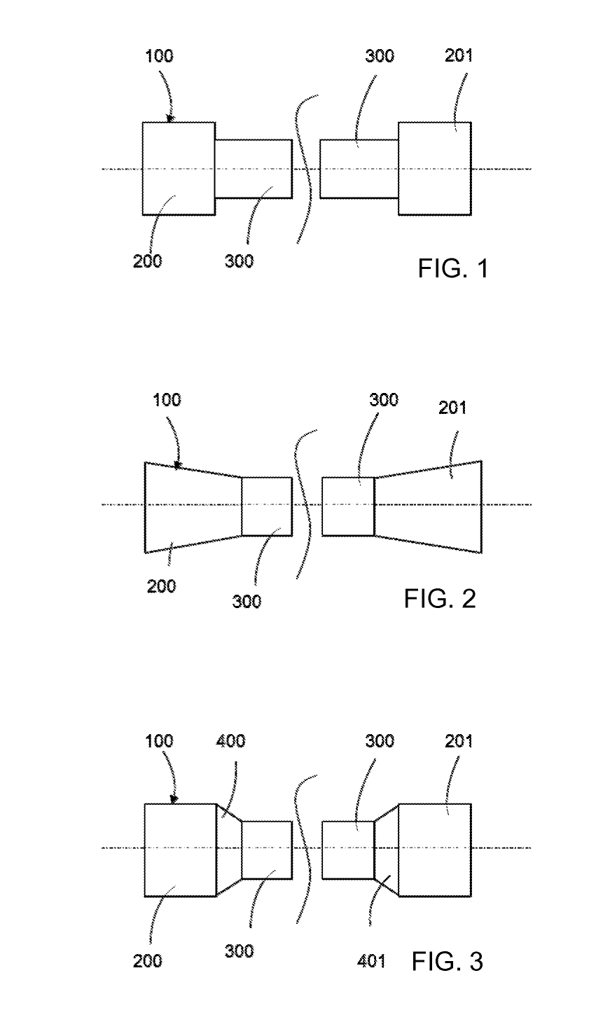

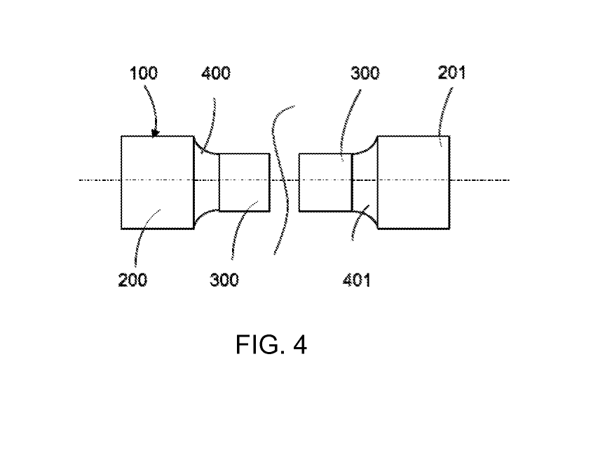

The invention is described by way of example below. FIG. 1, FIG. 2, FIG. 3 and FIG. 4 schematically show the outer contours of the embodiments of the invention. All embodiments have a tubular shape having a constant internal diameter over the entire length, although this is not shown in the figures. The dimensions, in particular the diameter ratio of tubular sections X and Y, are not shown to scale.

FIG. 1 shows a tubular target according to the invention -100-, where the ends of the tube are each configured as tubular sections X and denoted by -200- and -201-. A tubular section -300- is arranged between the tubular sections -200- and -201-. The tubular sections X -200- and -201- each have a constant external diameter ADx over their entire length. The tubular section Y -300- also has a constant external diameter ADy over the entire length. The tubular target is made in one piece.

FIG. 2 shows a tubular target according to the invention -100-, where the ends of the tube are each configured as tubular sections X and denoted by -200- and -201-. A tubular section Y -300- is arranged between the tubular sections -200- and -201-. The tubular sections -200- and -201- are conical. The tubular target is made in one piece.

FIG. 3 shows a tubular target according to the invention -100-, where the ends of the tube are each configured as tubular sections X and denoted by -200- and -201-. The tubular sections -200- and -201- each have a constant external diameter ADx over the entire length. The middle region of the tubular target -100- is configured as tubular section Y -300-. The tubular section Y has a constant external diameter ADy over the entire length. The sections Z -400- and -401- are located between the tubular sections -200- and -300- and the tubular sections -201- and -300-. The sections Z -400- and -401- are each configured as a frustum of a cone. The tubular target is made in one piece.

FIG. 4 shows a tubular target according to the invention -100-, where the ends of the tube are each configured as tubular sections X -200- and -201-. The middle region of the tubular target -100- is configured as tubular section Y -300-. The sections Z -400- and -401- are located between the tubular sections -200- and -300- and the tubular sections -201- and -300-. The sections Z -400- and -401- are provided with a radius. The tubular target -100- is made in one piece.

The production according to the invention of tubular refractory metal targets is described by way of example below.

### EXAMPLE 1

Mo powder having a particle size (FSSS) of 4.2 μm was introduced into a rubber tube which had a diameter of 420 mm and was closed at one end and in the middle of which a steel mandrel having a diameter of 147 mm was positioned. The rubber tube was closed and densified in a cold isostatic press at a pressure of 210 MPa. The green body had a relative density of 0.65. The green body produced in this way was sintered at a temperature of 1900° C. in an indirect sintering furnace. The relative sintered density was 0.94.

After the sintering process, the tubular blank was machined on all sides; the external diameter was 243 mm and the internal diameter was 130 mm. Extrusion was carried out on a 3000 t indirect ram extruder. The tubular blank was for this purpose heated to a temperature of 1250° C. Subsequently, the tubular blank was pressed over a mandrel to form an extruded tube having an external diameter of about 200 mm and an internal diameter of 125 mm. In the middle the predeformed tubular blank was deformed to a degree of deformation |φ| of 0.03 by forging, forming a tubular section -300- as shown in FIG. 1. The tubular sections X -200-, -201- each had a length of 150 mm. The density was determined as indicated in the description. The density in the region Y was almost 10.2 g/cm². (RDy−RDx)/RDy was 0.001.

### EXAMPLE 2

The production of the tubular blank and extrusion were carried out as described in Example 1. In the middle, the predeformed tubular blank was deformed by a degree of deformation |φ| of 0.33 by forging, forming a tubular section -300- as shown in FIG. 1. The tubular sections X -200-, -201- each had a length of 150 mm. The density was determined as indicated in the description. The density in the region Y was 10.2 g/cm². (RDy−RDx)/RDy was 0.005.

### EXAMPLE 3

The production of the tubular blank was carried out using a method based on Example 1; after machining the tubular blank on all sides, the external diameter was 190 mm and the internal diameter was 130 mm. The subsequent forging was carried out on a 500 t forging machine. The tubular blank was for this purpose heated to a temperature of 1300° C. The initial and end regions of the tube were as per FIG. 1 each forged to a length of about 100 mm to an external diameter ADx of 169 mm with a density of about 10.0 g/cm³ and the middle region was forged to an external diameter ADy=155 mm with a density of about 10.2 g/cm³. (RDy−RDx)/RDy was 0.02.

### EXAMPLE 4

The production of the tubular blank was carried out using a method based on Example 1; after machining the tubular blank on all sides, the external diameter was 175 mm and the internal diameter was 130 mm. The subsequent forging was carried out on a 500 t forging machine. The tubular blank was for this purpose heated to a temperature of 1300° C. The heated tubular blank as per FIG. 1 was subsequently forged in the middle region of the tube to an external diameter Ady=155 mm with a density of about 10.1 g/cm³. (RDy−RDx)/RDy was 0.05.

### EXAMPLE 5

A round plate having a diameter of 60 mm and a density of 8.70 g/cm³ was produced by sintering at 1700° C. The sputtering behaviour was subsequently compared with a virtually 100% dense, deformed material.

### EXAMPLE 6

A round plate having a diameter of 60 mm and a density of 8.20 g/cm³ was produced by sintering at 1600° C. The sputtering behaviour was compared with a 100% dense, deformed material.

The characterization of the specimens from Examples 1 to 6 was carried out as described below. Planar experimental targets having a diameter of about 50 mm were in each case machined from the regions X and Y, or the sintered round plates as per Examples 5 and 6 were used, ground and soldered onto a copper backing plate by means of indium. Sputtering experiments were carried out at 1 kW and 1.3 Pa of argon, with an Si wafer serving as substrate. The time of the experiment was 10 hours.

The ablation of the target was then determined and the percentage difference ((ablation for specimen Y−ablation for specimen X) ablation for specimen Y)×100 (in %) was determined for Examples 1 to 4. The specimens as per Examples 5 and 6 were tested analogously and the following percentage difference was determined: ((ablation for deformed specimen−ablation for specimen which had only been sintered)/ablation for deformed specimen)×100 (in %).

For Example 1, this ratio was 1.0%; for Example 2, it was 1.7%; for Example 3, it was 1.9%; for Example 4, it was 2.8%; for Example 5, it was 8.1% and for Example 6, it was 12.0%. None of the specimens displayed an unacceptable tendency for arcing or particle generation to occur.

As indicated in detail in the description, increased ablation occurs at the region of the ends of the tube in the case of tubular targets due to the process. The magnitude of this increased ablation depends on the process conditions. A difference of from 1.0 to 12% can be compensated by means of the specimens as per Examples 1 to 6. A person skilled in the art can therefore firstly determine, in a simple way, the different ablation on a tubular target produced according to the prior art and then determine the optimum (RDy−RDx)/RDy value by means of a few experiments.

1-25. (canceled)

26. A tubular target, comprising:
a target body of refractory metal or a refractory metal alloy having a refractory metal content of ≧50 atom %;
said target body including at least one tubular section X having a relative density RDx, at least in regions thereof, and at least one tubular section Y having a relative density RDy, at least in regions thereof;
at least one said tubular section X having, at least in regions thereof, a greater external diameter than regions of said at least one tubular section Y (300); and
$$\frac{RDy - RDx}{RDy} \geq 0.001 .$$

27. The tubular target according to claim 26, wherein at least one said tubular section X, at least in regions thereof, has an external diameter ADx and at least one tubular section Y, at least in regions thereof, has an external diameter ADy, where
$$\frac{ADx - ADy}{ADx} \geq 0.01 .$$

28. The tubular target according to claim 27, wherein
$$\frac{ADx - ADy}{ADx} \geq 0.03 .$$

29. The tubular target according to claim 26, wherein said target body has ends configured, at least in regions thereof, as tubular sections X and at least one said tubular section Y, which extends along an axial direction over a longer region than a sum of an axial extension of said tubular sections X arranged therein between.

30. The tubular target according to claim 26, which further comprises a section Z disposed between at least one said tubular section X and one said tubular section Y, said section Z having an external diameter changing from ADx to ADy.

31. The tubular target according to claim 26, wherein at least one said tubular section X is conical.

32. The tubular target according to claim 26, wherein said body is a powder metallurgy product.

33. The tubular target according to claim 26, wherein at least one said tubular section X has a uniform and fine pore structure.

34. The tubular target according to claim 26, wherein said body consists of a material selected from the group consisting of molybdenum, a molybdenum alloy, tungsten, a tungsten alloy, chromium, and a chromium alloy.

35. The tubular target according to claim 26, wherein all said tubular sections X and all said tubular sections Y have an identical material composition.

36. The tubular target according to claim 26, wherein said body is formed in one piece.

37. The tubular target according to claim 26, wherein at least one said tubular section Y has a relative density of from 99 to 100%.

38. The tubular target according to claim 26, wherein at least one said tubular section X has an average density RDxm, at least in regions over a length in an axial direction of 50 mm, and at least one tubular section Y has an average relative density RDym, at least in regions over a length in the axial direction of 50 mm, where
$$\frac{RDxm - RDym}{RDxm} \geq 0.001 .$$

39. The tubular target according to claim 38, wherein at least one of the following is true:
$$\frac{RDy - RDx}{RDy} \geq 0.01 and \text{/} or \frac{RDxm - RDym}{RDxm} \geq 0.01 .$$

40. The tubular target according to claim 38, wherein at least one of the following is true:
$$\frac{RDy - RDx}{RDy} \leq 0.02 and \text{/} or \frac{RDxm - RDym}{RDxm} \leq 0.02 .$$

41. The tubular target according to claim 26, configured as a target for producing a functional layer of a thin-film solar cell or a TFT structure.

42. A method of producing a tubular target, comprising the following steps:
providing a powder of refractory metal or a refractory metal alloy having a refractory metal content of ≧50 atom %;
producing a green body by pressing the powder at a pressing pressure p, where 100 MPa<p<400 MPa;
producing a tubular blank by pressure-less or pressure-aided sintering at a homologous temperature of between 0.4 and 0.9 and optional mechanical shaping, to form a tubular target having at least one tubular section X and at least one tubular section Y;
wherein the tubular blank is deformed in a region which in the finished tubular target corresponds to the tubular section Y with a degree of deformation that is, at least regionally, greater than in a region that corresponds to the tubular section X the finished tubular target.

43. The method according to claim 42, which comprises deforming the tubular blank at least regionally |φ|≧0.03 in the region which in the finished tubular target corresponds to the tubular section X to a greater extent than regionally within a region that corresponds to the tubular section X in the finished tubular target.

44. The method according to claim 42, which comprises forming the tubular blank with a relative density RDr, where RDr 0.8≦RDr≦0.995.

45. The method according to claim 42, wherein the tubular section Y is formed, at least in regions, with a smaller external diameter than the tubular section X.

46. The method according to claim 42, which comprises producing the green body by cold isostatic pressing, where the green body has a shape selected from the group consisting of a tube, a cylinder, a tube having a greater external diameter in regions and a cylinder having a greater external diameter in regions.

47. The method according to claim 42, wherein the tubular section X is not deformed at least in regions thereof.

48. The method according to claim 42, which comprises deforming the tubular blank by at least one process selected from the group consisting of forging, extrusion, and pressure rolling.

49. The method according to claim 42, which comprises producing a tubular target by mechanical shaping of the deformed tubular blank and optionally joining the tubular target to a support tube.

50. The method according to claim 42, which comprises forming a tubular target according to claim 26.
